(19) United States
(12) Patent Application Publication
(10) Pub. No.: US 2012/0058576 A1
(43) Pub. Date: Mar. 8, 2012

(54) Deposition System

(76) Inventors: Markus E. Beck, Scotts Valley, CA (US); Ashish Bodke, San Jose, CA (US); Yacov Elgar, Sunnyvale, CA (US); Dhruv Gajaria, Mountain View, CA (US); Raffi Garabedian, Los Altos, CA (US); Jing Guo, Santa Clara, CA (US); Erel Milshtein, Cupertino, CA (US)

(21) Appl. No.: 13/224,460

(22) Filed: Sep. 2, 2011

Related U.S. Application Data
(60) Provisional application No. 61/379,771, filed on Sep. 3, 2010.

(51) Int. Cl. H01L 21/66; B05C 11/10

(52) U.S. Cl. 438/5; 118/695; 257/E21.528

(57) ABSTRACT

A pumping and valve control device can be used in an atomic layer deposition system.

### CLAIM FOR PRIORITY

This application claims priority under 35 U.S.C. §119(e) to Provisional U.S. Patent Application Ser. No. 61/379,771, filed on Sep. 3, 2010, which is hereby incorporated by reference.

### TECHNICAL FIELD

This invention relates to a pumping and valve control device. The pumping and valve control device can be used in an atomic layer deposition system.

### BACKGROUND

Atomic layer deposition (ALD) is a thin film deposition technique that is based on the sequential use of a gas phase chemical process. Since the amount of film material deposited in each reaction cycle can be constant, ALD can be a self-limiting, sequential surface chemistry that deposits conformal thin-films of materials onto substrates of varying compositions.

### DESCRIPTION OF DRAWINGS

FIG. 1 is a diagram illustrating an atomic layer deposition process.

FIG. 2 is a diagram illustrating an atomic layer deposition process.

FIG. 3 is a diagram illustrating an atomic layer deposition process.

FIG. 4 is a diagram illustrating an atomic layer deposition system.

### DETAILED DESCRIPTION

Photovoltaic devices can include multiple layers formed on a substrate (or superstrate). For example, a photovoltaic device can include a conducting layer, a semiconductor absorber layer, a buffer layer, a semiconductor window layer, and a transparent conductive oxide (TCO) layer, formed in a stack on a substrate. Each layer may in turn include more than one layer or film. For example, the semiconductor window layer and semiconductor absorber layer together can be considered a semiconductor layer. The semiconductor layer can include a first film created (for example, formed or deposited) on the TCO layer and a second film created on the first film. Additionally, each layer can cover all or a portion of the device and/or all or a portion of the layer or substrate underlying the layer. For example, a “layer” can mean any amount of any material that contacts all or a portion of a surface.

Atomic layer deposition is a thin film deposition technique that is based on the sequential use of a gas phase chemical process. By using ALD, film thickness depends only on the number of reaction cycles, which makes the thickness control accurate and simple. Unlike chemical vapor deposition (CVD), there is less need of reactant flux homogeneity, which gives large area (large batch and easy scale-up) capability, excellent conformality and reproducibility, and simplifies the use of solid precursors. Furthermore, the growth of different multilayer structures is straight forward. However, a major limitation of ALD is its low deposition rate. Therefore, multiple substrates are processed at the same time in most of practical application.

The growth of material layers by ALD consists of repeating the following characteristic four steps: 1) exposure of the first precursor, 2) purge or evacuation of the reaction chamber to remove the non-reacted precursors and the gaseous reaction by-products, 3) exposure of the second precursor—or another treatment to activate the surface again for the reaction of the first precursor, 4) Purge or evacuation of the reaction chamber. Each reaction cycle adds a given amount of material to the surface, referred to as the growth per cycle. The majority of ALD reactions use two chemicals, typically called precursors. These precursors react with a surface one-at-a-time in a sequential manner. By exposing the precursors to the growth surface repeatedly, a thin film is deposited. In some embodiments, manufacturing process can include more than one ALD, which can be performed in different reaction chambers.

Similar in chemistry to chemical vapor deposition (CVD), except that the ALD reaction breaks the CVD reaction into two half-reactions, keeping the precursor materials separate during the reaction. Additionally, ALD film growth is self-limited and based on surface reactions, which makes achieving atomic scale deposition control possible. By keeping the precursors separate throughout the coating process, atomic layer thickness control of film grown can be obtained as fine as atomic/molecular scale per monolayer. ALD includes releasing sequential precursor gas pulses to deposit a film one layer at a time on the substrate. The precursor gas can be introduced into a process chamber and produces a precursor monolayer of material on the device surface. A second precursor of gas can be then introduced into the chamber reacting with the first precursor to produce a monolayer of film on the substrate/absorber surface.

The precursor monolayers (for example, a metal precursor monolayer or chalcogen precursor monolayer) can have a thickness of less than about two molecules, for example, about one molecule. After the precursors react, the resulting metal chalcogenide layer can also have a thickness of less than about two molecules, for example, about one molecule. A monolayer, for example, a precursor monolayer or a metal chalcogenide monolayer can be continuous or discontinuous and can contact all or a portion of a surface. For example, a monolayer can contact more that about 80%, more than about 85%, more than about 90%, more than about 95%, more than about 98%, more than about 99%, more than about 99.9%, or about 100% of a surface. ALD can progress by two fundamental mechanisms: chemisorption saturation process and sequential surface chemical reaction process.

Given the nature of ALD, valve and pumping operation need to be synchronized to achieve higher precursor utilization efficiency and better control of processing time. An atomic layer deposition system with optimized pumping and valve control is developed to achieve dynamic pumping speed control.

In one aspect, a deposition system can include an inlet valve for introducing a processing gas into a reaction chamber, a reaction chamber adjacent to the inlet valve having a deposition temperature and deposition pressure and configured to form a layer of material on a substrate by atomic vapor deposition, a pump adjacent to the reaction chamber, an outlet regulation valve adjacent to the reaction chamber, and a control module for dynamic control of the adjustable pumping speed of the pump and synchronization between the inlet valve and regulation valve to achieve high utilization rate and flow uniformity of the processing gas. The inlet valve can have a short reaction time. The pump can have an adjustable pumping speed to control the pressure in the reaction chamber and evacuation speed of the reaction chamber. The outlet regulation valve can have a short reaction time and being synchronized with the inlet valve.

The system can include a conveyor for transferring a substrate to the reaction chamber. The system can include a plurality of substrates capable of being transferred to the reaction chamber. The plurality of substrates can be parallel processed in the reaction chamber. The reaction time of the inlet valve can be less than 10 milliseconds. The reaction time of the outlet regulation valve can be less than 10 milliseconds. The reaction time of the outlet regulation valve can be at least 10 milliseconds.

The processing gas can include at least one precursor gas for forming the layer of material on the substrate by atomic vapor deposition. The precursor gas can include at least one material selected from the group containing diethylzinc, hydrogen sulfide, and water. The processing gas can include at least one cleaning gas for purging the reaction chamber. The cleaning gas can include nitrogen.

The reaction chamber can have a volume and the volume can be predetermined to optimize an atomic vapor deposition. The reaction chamber can have a geometry and the geometry can be designed to obtain uniform processing gas flow on the substrate surface. The control module can include a proportional integral derivative controller monitoring and controlling temperature and pressure conditions in the reaction chamber. The system can include at least one temperature sensor for measuring the substrate temperature.

In another aspect, a method of atomic layer deposition can include transferring a substrate to a reaction chamber, pulsing a first precursor gas into the reaction chamber through an inlet valve to form a first monolayer on a surface of the substrate, evacuating the first precursor gas from the reaction chamber through an outlet regulation valve, and pulsing a second precursor gas into the reaction chamber through the inlet valve. The second precursor gas can react with the first monolayer on the surface to form a second monolayer on the surface of the substrate and at least one purgable material in the reaction chamber. The method can include purging the purgable material from the reaction chamber through the outlet regulation valve. The inlet valve and outlet regulation valve can have short reaction time and can be synchronized.

The method can include pulsing an inert gas into the reaction chamber to flush the first precursor gas out of the reaction chamber. The method can include pulsing an inert gas into the reaction chamber to flush the purgable material out of the reaction chamber. The first precursor gas can include diethylzinc. The second precursor gas can include at least one material selected from the group containing hydrogen sulfide and water. The inert gas can include nitrogen.

The method can include real-time controlling the first precursor gas evacuating speed for optimizing the atomic vapor deposition. The method can include real-time controlling the purgable material purging speed for optimizing the atomic vapor deposition. The reaction time of the inlet valve can be less than 10 milliseconds. The reaction time of the outlet regulation valve can be less than 10 milliseconds. The reaction time of the outlet regulation valve can be at least 10 milliseconds.

The method can include monitoring and controlling temperature and pressure conditions in the reaction chamber by a control module. The method can include measuring the substrate temperature by at least one pyrometer. The method can include measuring the substrate temperature by at least one contact sensor. The method can include heating the substrate before pulsing the first or second precursor gas.

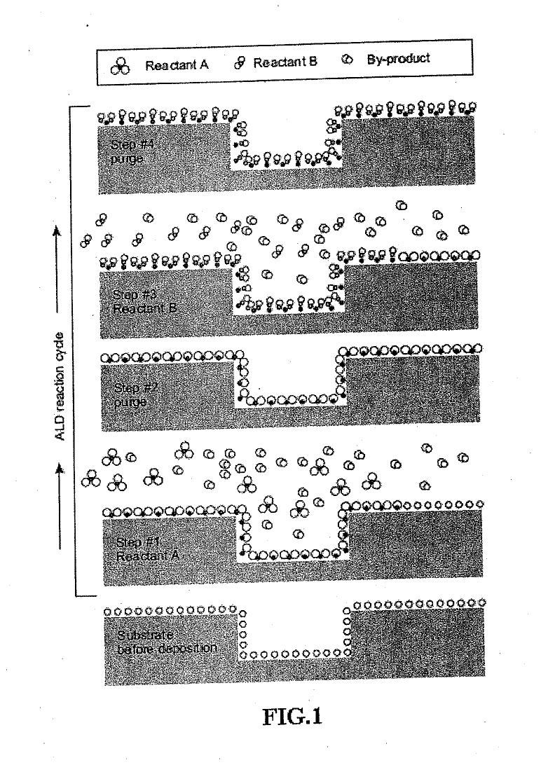

Atomic layer deposition (ALD) utilizes sequential precursor gas pulses to deposit a film one layer at a time. ALD can be used in photovoltaic module manufacturing process. A photovoltaic device can include a conducting layer, a semiconductor absorber layer, a buffer layer, a semiconductor window layer, and a transparent conductive oxide (TCO) layer, formed in a stack on a substrate. For example, ALD can be used to deposit at least one layer, such as buffer layer. As shown in FIG. 1, a first precursor gas can be introduced into the reaction chamber (step 1 in FIG. 1) and produce a monolayer of chemisorbed species on the substrate surface (step 2 in FIG. 1). A second precursor gas can be then introduced into the reaction chamber reacting with the chemisorbed monolayer (step 3 in FIG. 1) to form a monolayer of deposited film on the substrate surface (step 4 in FIG. 1). Due to the self-limiting nature of the half-reactions, the thickness of the deposited film can be precisely controlled by the number of deposition cycles. Between the introductions of two precursor gases, a purging step with nitrogen gas can be included to purge the reaction chamber.

In some embodiments, ALD can be used to deposit a buffer layer of a photovoltaic device including a metal chalcogenide, such as indium sulfide (e.g., In₂S₃), indium oxide (e.g., In₂O₃), or indium selenide (e.g., In₂Se₃) (or combinations thereof), zinc sulfide (e.g., ZnS), zinc oxide (e.g., ZnO), or zinc selenide (ZnSe) (or combinations thereof). In some embodiments, the first precursor gas can include diethylzinc (e.g., DEZ), dimethylzinc (e.g., DMZ), trimethylindium (e.g., TMI), indium(III) acetylacetonate (e.g., In(acac)₃), cyclopentadienyl indium(I) (e.g., InCp). The second precursor gas can include hydrogen sulfide, water vapor or hydrogen selenide.

These layers can be formed with various combinations of individual sub-layers. For example, a first buffer monolayer can include indium sulfide (e.g., In₂S₃), indium oxide (e.g., In₂O₃), or indium selenide (e.g., In₂Se₃) or any suitable indium chalcogenide (e.g., In₂(O,S,Se)₃), or zinc sulfide (e.g., ZnS), zinc oxide (e.g., ZnO), or zinc selenide (e.g., ZnSe) or any suitable zinc chalcogenide (e.g., Zn(O,S,Se)). One or more additional monolayers of the same or differing compositions can be formed on the first monolayer. For example, the second monolayer can include indium sulfide (e.g., In₂S₃), indium oxide (e.g., In₂O₃), or indium selenide (e.g., In₂Se₃) or any suitable indium chalcogenide (e.g., In₂(O,S,Se)₃), or zinc sulfide (e.g., ZnS), zinc oxide (e.g., ZnO), zinc selenide (e.g., ZnSe) or any suitable zinc chalcogenide (e.g., Zn(O,S,Se)).

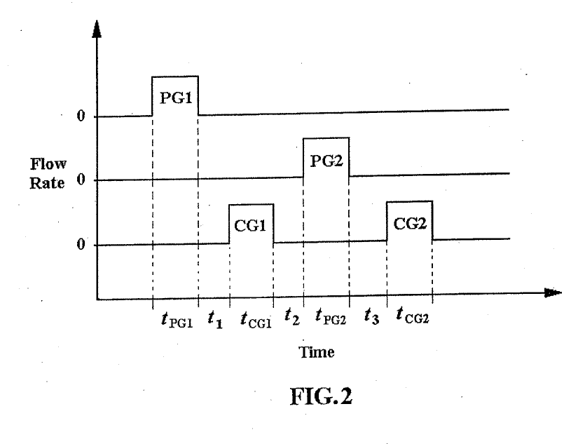

As shown in FIG. 2, a deposition cycle of atomic layer deposition can include: (1) a first precursor gas pulse (PG1 in FIG. 2), (2) a first cleaning gas pulse to purge the chamber (CG1 in FIG. 2), (3) a second precursor gas pulse (PG2 in FIGS. 2), and (4) a second cleaning gas pulse to purge the chamber (CG2 in FIG. 2). In some embodiments, the first precursor gas can include diethylzinc (e.g., DEZ), dimethyizinc (e.g., DMZ), trimethylindium (e.g., TMI), indium(III) acetylacetonate (e.g., In(acac)₃), cyclopentadienyl indium(I) (e.g., InCp). The second precursor gas can include hydrogen sulfide, water vapor or hydrogen selenide. The cleaning gas can include nitrogen and Argon. In FIG. 2, the lengths of first precursor gas pulse PG1, first cleaning gas pulse CG1, second precursor gas pulse PG2, and second cleaning gas pulse CG2 are represented as t_{PG1}, t_{CG1}, t_{PG2}, and t_{CG2}, respectively. The time spacings between the gas pulses are represented as t₁, t₂, and t₃. The pulse lengths can be in any suitable range in millisecond scale. Atomic layer deposition system can include two or more source gas delivery modules with high actuation speed valves to control the length of gas pulses. The gases can be introduced into a heated reaction chamber. Vacuum pumping can be used to control the system pressure, gas flow and insure rapid purging of the reaction chamber after each deposition cycle. For better precursor utilization rate and system efficiency, the lengths and spacing of each gas pulse (such as t_{PG1}, t_{CG1}, t_{PG2}, t_{CG2}, t₁, t₂, and t₃ in FIG. 2) need to be precisely managed.

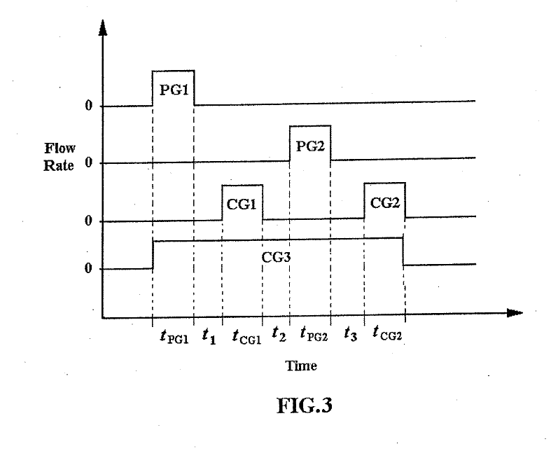

As shown in FIG. 3, in some embodiments, a deposition cycle of atomic layer deposition can include a continuous flow of a gas (CG3). It can include an inert gas as a carrying gas. It can include a cleaning gas.

An atomic layer deposition system with pumping and valve control is developed for dynamic pumping speed and valve control. The dynamic control pumping speed can be obtained by using fast synchronized regulation valve (0-100% of nominal speed) with short reaction time. Further, the atomic layer deposition system can
1. synchronize between regulation valve operation and precursor purging valve to optimize precursor utilization;
2. perform maximum pumping speed during evacuation and shorten the cleaning gas purging time;
3. achieve better control to optimize the process for precursor flow uniformity and reaction pressure.

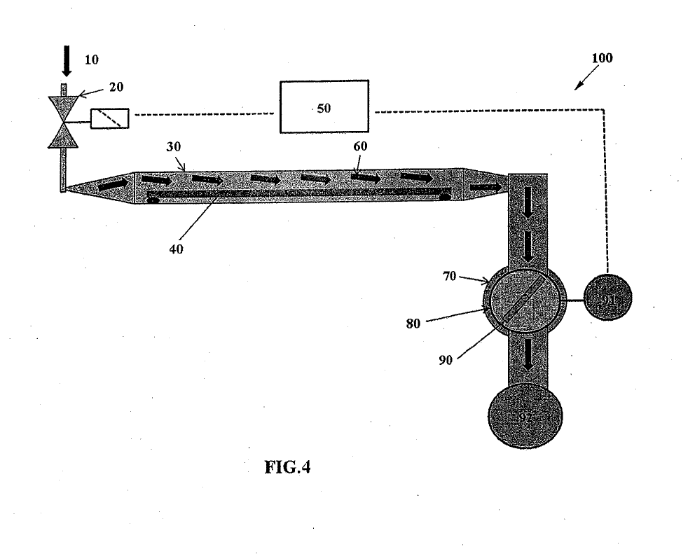

As shown in FIG. 4, in atomic layer deposition system 100, precursor/carrying gas and cleaning gas 10 can be introduce into reaction chamber 30 through valve 20. Valve 20 can be any suitable fast valve, such as fast solenoid valve. Specifically, valve 20 can be controlled by an electric current through any suitable actuating device, such as a solenoid coil (not shown).

Substrate 40 can be positioned in reaction chamber 30. In some embodiments, system 100 can include a substrate lift beneath a substrate position in reaction chamber 30 to lift a substrate into reaction chamber 30 and reaction chamber 30. System 100 can include conveyor transferring a substrate from reaction chamber 30 to a downstream process. With dynamic control pumping speed, process gas flow 60 can have controlled flow speed and pressure. Heater 70 can be included to control the temperature in reaction chamber 30.

Reaction chamber 40 can be maintained at any suitable conditions, including any suitable temperature and pressure. Reaction chamber 40 can have a deposition temperature of about 75 degrees C. to about 300 degrees C., about 75 degrees C. to about 270 degrees C., about 75 degrees C. to about 250 degrees C., about 75 degrees C. to about 150 degrees C., about 100 degrees C. to about 300 degrees C., about 100 degrees C. to about 200 degrees C., about 100 degrees C. to about 150 degrees C., about 150 degrees C. to about 350 degrees C., about 150 degrees C. to about 300 degrees C., about 150 degrees C. to about 250 degrees C., about 150 degrees C. to about 200 degrees C., or about 170 degrees C. to about 500 degrees C. Reaction chamber 40 can be have any suitable deposition pressure, including 10⁻⁷-1000 Torr, 10⁻⁷-20 Torr, 10⁻⁷-10 Torr, 5-10 Torr, 5 mTorr-500 mTorr, 5 mTorr-100 mTorr, 5 mTorr-50 mTorr, or 0.1 mTorr-10 mTorr.

Fast synchronized regulation valve 80 can be included with motor 91 and rotor 90. Valve 80 can have 0-100% of nominal speed with short reaction time. The reaction time of valve 80 can be in any suitable range for optimized deposition, such as less than 100 milliseconds, less than 50 milliseconds, less than 10 milliseconds, or less than 5 milliseconds. Vacuum pump 92 can be included to pump process gases from reaction chamber 30 and control the pressure.

With the dynamic control of pumping speed and fast synchronized regulation valve, atomic layer deposition system 100 can achieve better control of total cycle time. In some embodiments, longer cycle time is good for pure ALD process.

Volume of reaction chamber 30 can be optimized to control the cycle time and the deposition process. Reaction pressure can be controlled by dynamic control of pumping speed and fast synchronized regulation valve. For example, low pressure can be good for pure ALD, while high pressure will increase the growth but might start CVD process.

Atomic layer deposition system 100 can include control module 50 for dynamic control of pumping speed of pump 92, base pressure, and synchronization of regulation valve 20.

Pumping speed can be controlled in atomic layer deposition system 100 for achieving optimized balance between evacuation speed and precursors consumption. Atomic layer deposition system 100 can control precursor flow to create gas uniformity on substrate surface by optimized geometry and gas flow speed.

With dynamic control of pumping speed and base pressure, better evacuation efficiency can be achieved by efficient removal previous precursor remains before starting the pulse of precursor gases.

Atomic layer deposition system 100 can have the capability to be integrated into a production line coating individual substrates and to handle multiple substrates, wafers or panels automatically and simultaneously. In some embodiments, the tool can include multiple process and/or reaction chambers capable of applying ALD coatings simultaneously onto substrates, wafers or panels. In some embodiments, multiple chambers can be used to deposit layers sequentially. Therefore, if the growth temperature or pressure varies in a deposition process, the substrate can stay in the same tool, but be moved to a different chamber for a sequential stage. Control module 50 for dynamic control of pumping speed, base pressure, and synchronization between the inlet valve and regulation valve can be used in any suitable deposition process, such as CVD, PECVD, MOCVD, APCVD, or LPCVD.

While the invention has been shown and explained in the embodiment described herein, it is to be understood that the invention should not be confined to the exact showing of the drawings, and that any variations, substitutions, and modifications are intended to be comprehended within the spirit of the invention. Other embodiments are within the claims.

What is claimed is:

1. A deposition system comprising:
an inlet valve for introducing a processing gas into a reaction chamber, the inlet valve having a short reaction time;
a reaction chamber adjacent to the inlet valve having a deposition temperature and deposition pressure and configured to form a layer of material on a substrate by atomic vapor deposition;
a pump adjacent to the reaction chamber, wherein the pump have an adjustable pumping speed to control the pressure in the reaction chamber and evacuation speed of the reaction chamber;
an outlet regulation valve adjacent to the reaction chamber, the outlet regulation valve having a short reaction time and being synchronized with the inlet valve; and
a control module for dynamic control of the adjustable pumping speed of the pump and synchronization between the inlet valve and regulation valve to achieve high utilization rate and flow uniformity of the processing gas.

2. The system of claim 1, further comprising a conveyor for transferring a substrate to the reaction chamber.

3. The system of claim 1, further comprising a plurality of substrates capable of being transferred to the reaction chamber, wherein the plurality of substrates can be parallel processed in the reaction chamber.

4. The system of claim 1, wherein the reaction time of the inlet valve is less than 10 milliseconds.

5. The system of claim 1, wherein the reaction time of the outlet regulation valve is less than 10 milliseconds.

6. The system of claim 1, wherein the reaction time of the outlet regulation valve is at least 10 milliseconds.

7. The system of claim 1, wherein the processing gas comprises at least one precursor gas for forming the layer of material on the substrate by atomic vapor deposition.

8. The system of claim 7, wherein the precursor gas comprises at least one material selected from the group containing diethylzinc, hydrogen sulfide, and water.

9. The system of claim 1, wherein the processing gas comprises at least one cleaning gas for purging the reaction chamber.

10. The system of claim 9, wherein the cleaning gas comprises nitrogen.

11. The system of claim 1, wherein the reaction chamber has a volume and the volume is predetermined to optimize an atomic vapor deposition.

12. The system of claim 1, wherein the reaction chamber has a geometry and the geometry is designed to obtain uniform processing gas flow on the substrate surface.

13. The system of claim 1, wherein the control module comprises a proportional integral derivative controller monitoring and controlling temperature and pressure conditions in the reaction chamber.

14. The system of claim 1, further comprising at least one temperature sensor for measuring the substrate temperature.

15. A method of atomic layer deposition comprising:
pulsing a first precursor gas into a reaction chamber through an inlet valve to form a first monolayer on a surface of a substrate in the reaction chamber;
evacuating the first precursor gas from the reaction chamber through an outlet regulation valve;
pulsing a second precursor gas into the reaction chamber through the inlet valve, wherein the second precursor gas reacts with the first monolayer on the surface to form a second monolayer on the surface of the substrate and at least one purgable material in the reaction chamber; and
purging the purgable material from the reaction chamber through the outlet regulation valve, wherein the inlet valve and outlet regulation valve have short reaction time and are synchronized.

16. The method of claim 15, further comprising pulsing an inert gas into the reaction chamber to flush the first precursor gas out of the reaction chamber.

17. The method of claim 15, further comprising pulsing an inert gas into the reaction chamber to flush the purgable material out of the reaction chamber.

18. The method of claim 15, wherein the first precursor gas comprises diethylzinc.

19. The method of claim 15, wherein the second precursor gas comprises at least one material selected from the group containing hydrogen sulfide and water.

20. The method of claim 16, wherein the inert gas comprises nitrogen.

21. The method of claim 17, wherein the inert gas comprises nitrogen.

22. The method of claim 15, further comprising transferring the substrate to the reaction chamber.

23. The method of claim 15, further comprising real-time controlling the first precursor gas evacuating speed for optimizing the atomic vapor deposition.

24. The method of claim 15, further comprising real-time controlling the purgable material purging speed for optimizing the atomic vapor deposition.

25. The method of claim 15, wherein the reaction time of the inlet valve is less than 10 milliseconds.

26. The method of claim 15, wherein the reaction time of the outlet regulation valve is less than 10 milliseconds.

27. The method of claim 15, wherein the reaction time of the outlet regulation valve is at least 10 milliseconds.

28. The method of claim 15, further comprising monitoring and controlling temperature and pressure conditions in the reaction chamber by a control module.

29. The method of claim 15, further comprising measuring the substrate temperature by at least one pyrometer.

30. The method of claim 15, further comprising measuring the substrate temperature by at least one contact sensor.

31. The method of claim 15, further comprising heating the substrate before pulsing the first or second precursor gas.
